(19) United States
(12) Patent Application Publication
(10) Pub. No.: US 2024/0420983 A1
(43) Pub. Date: Dec. 19, 2024

(54) TRANSFER HEAD AND METHOD OF FORMING SAME

(71) Applicant: XEROX CORPORATION, Norwalk, CT (US)

(72) Inventors: Christopher L. Chua, San Jose, CA (US); Yu Wang, Union City, CA (US)

(21) Appl. No.: 18/209,562

(22) Filed: Jun. 14, 2023

(51) Int. Cl. H01L 21/683; C09D 133/14

(52) U.S. Cl. CPC H01L 21/683; C09D 133/14

(57) ABSTRACT

Various embodiments of a transfer head and a method of forming such transfer head are disclosed. The transfer head includes a transfer layer including a thermally-switchable shape memory polymer material. The method includes heating a polymer precursor material above a melting point temperature Tₘ of the polymer precursor material, heating a substrate to a first temperature T₁ greater than Tₘ, and disposing the heated polymer precursor material on a first major surface of the substrate to form a coated substrate. The method further includes exposing the coated substrate to electromagnetic radiation while maintaining the temperature of the coated substrate at T₁, reducing the temperature of the substrate to a second temperature T₂ less than Tₘ while maintaining exposure of the coated substrate to the electromagnetic radiation, and removing the coated substrate from exposure to the electromagnetic radiation to form the transfer layer.

### SUMMARY

In general, the present disclosure provides various embodiments of a transfer head and a method of manufacturing such transfer head. The transfer head can include a transfer layer with thermally- or optically-activated, repeatable, and reversible rigid-to-soft transitions to facilitate object (e.g., chiplet) mass transfer. In one or more embodiments, the transfer layer can be formed by disposing a polymer precursor material onto a substrate that is heated to a first temperature T₁ that is greater than a melting point temperature Tₘ of the polymer precursor material. The polymer precursor material forms a coated substrate that can be exposed to electromagnetic radiation while the temperature of the coated substrate is maintained at Ti. While the coated substrate remains exposed to the electromagnetic radiation, the temperature of the substrate can be reduced to a second temperature T₂ that is less than Tₘ. The coated substrate can then be removed from exposure to the electromagnetic radiation to form the transfer layer, which includes a thermally-switchable shape memory polymer material.

In one aspect, the present disclosure provides a method of forming a transfer head including a transfer layer that includes a thermally-switchable shape memory polymer material. The method includes heating a polymer precursor material above a melting point temperature Tₘ of the polymer precursor material; heating a substrate to a first temperature T₁ greater than Tₘ, where the substrate includes a first major surface and a second major surface; and disposing the heated polymer precursor material on the first major surface of the substrate to form a coated substrate. The method further includes exposing the coated substrate to electromagnetic radiation while maintaining the temperature of the coated substrate at Ti, reducing the temperature of the substrate to a second temperature T₂ less than Tₘ while maintaining exposure of the coated substrate to the electromagnetic radiation, and removing the coated substrate from exposure to the electromagnetic radiation to form the transfer layer.

In another aspect, the present disclosure provides a transfer head that includes a substrate including a first major surface and a second major surface, and a transfer layer spin coated onto the first major surface of the substrate and including a transfer surface opposite the first major surface of the substrate, where the transfer layer includes a thermally-switchable shape memory polymer material that undergoes a phase change when heated. The transfer surface of the transfer layer is configured to be placed in contact with an outward-facing side of a chiplet during a transfer operation. Further, the transfer layer has a total thickness variation of less than 8 micrometers.

In another aspect, the present disclosure provides a transfer apparatus that includes a transfer head. The transfer head includes a substrate including a first major surface and a second major surface, and a transfer layer spin coated onto the first major surface of the substrate and including a transfer surface opposite the first major surface of the substrate. The transfer layer includes a thermally-switchable shape memory polymer material that undergoes a phase change when heated. Further, the transfer surface of the transfer layer is configured to be placed in contact with an outward-facing side of a chiplet during a transfer operation. The transfer layer has a total thickness variation of less than 5 cm. The transfer apparatus further includes an energy source configured to apply energy to the transfer head to selectively heat a region of the transfer layer that corresponds to a location of the chiplet. The region is configured to hold the chiplet when the energy is removed during the transfer operation. The region is configured to be subsequently heated during the transfer operation to release the chiplet. Further, the transfer layer is reusable for repeated transfer operations.

In another aspect, the present disclosure provides a system for manufacturing a transfer head. The system includes a mounting fixture for holding a substrate, where the substrate includes a first major surface and a second major surface, where the second major surface of the substrate is disposed on a base of the mounting fixture; a heating apparatus configured to heat the substrate to a first temperature T₁ greater than a melting point temperature Tₘ of a polymer precursor material; and a dispenser configured to dispose the polymer precursor material on the first major surface of the substrate to form a coated substrate, where the polymer precursor material includes a bistable electroactive polymer (BSEP). The system further includes a smoothing apparatus configured to distribute the polymer precursor material on the first major surface of the substrate to further form the coated substrate, a vacuum chamber configured to receive the coated substrate, and an electromagnetic radiation source configured to direct electromagnetic radiation to the coated substrate in a vacuum environment when the coated substrate is disposed in the vacuum chamber. The heating apparatus is further configured to maintain the temperature of the coated substrate at T₁ as the electromagnetic radiation is directed to the coated substrate, and reduce the temperature of the coated substrate to a second temperature T₂ less than Tₘ while maintaining exposure of the coated substrate to the electromagnetic radiation.

All headings provided herein are for the convenience of the reader and should not be used to limit the meaning of any text that follows the heading, unless so specified.

The terms “comprises” and variations thereof do not have a limiting meaning where these terms appear in the description and claims. Such terms will be understood to imply the inclusion of a stated step or element or group of steps or elements but not the exclusion of any other step or element or group of steps or elements. The term “consisting of” means “including,” and is limited to whatever follows the phrase “consisting of.” Thus, the phrase “consisting of” indicates that the listed elements are required or mandatory and that no other elements may be present. The term “consisting essentially of” means including any elements listed after the phrase, and is limited to other elements that do not interfere with or contribute to the activity or action specified in the disclosure for the listed elements. Thus, the phrase “consisting essentially of” indicates that the listed elements are required or mandatory, but that other elements are optional and may or may not be present depending upon whether or not they materially affect the activity or action of the listed elements.

The words “preferred” and “preferably” refer to embodiments of the disclosure that may afford certain benefits, under certain circumstances; however, other embodiments may also be preferred, under the same or other circumstances. Furthermore, the recitation of one or more preferred embodiments does not imply that other embodiments are not useful, and is not intended to exclude other embodiments from the scope of the disclosure.

In this application, terms such as “a,” “an,” and “the” are not intended to refer to only a singular entity, but include the general class of which a specific example may be used for illustration. The terms “a,” “an,” and “the” are used interchangeably with the term “at least one.” The phrases “at least one of” and “comprises at least one of” followed by a list refers to any one of the items in the list and any combination of two or more items in the list.

As used herein, the term “or” is generally employed in its usual sense including “and/or” unless the content clearly dictates otherwise.

The term “and/or” means one or all of the listed elements or a combination of any two or more of the listed elements.

As used herein in connection with a measured quantity, the term “about” refers to that variation in the measured quantity as would be expected by the skilled artisan making the measurement and exercising a level of care commensurate with the objective of the measurement and the precision of the measuring equipment used. Herein, “up to” a number (e.g., up to 50) includes the number (e.g., 50).

Also herein, the recitations of numerical ranges by endpoints include all numbers subsumed within that range as well as the endpoints (e.g., 1 to 5 includes 1, 1.5, 2, 2.75, 3, 3.80, 4, 5, etc.).

These and other aspects of the present disclosure will be apparent from the detailed description below. In no event, however, should the above summaries be construed as limitations on the claimed subject matter, which subject matter is defined solely by the attached claims, as may be amended during prosecution.

### BRIEF DESCRIPTION OF THE DRAWINGS

Throughout the specification, reference is made to the appended drawings, where like reference numerals designate like elements, and wherein:

FIG. 1 is a schematic block diagram an exemplary assembly process utilizing micro-objects.

FIG. 2 is a schematic block diagram of the process of FIG. 1.

FIG. 3 is a schematic side view of an apparatus showing part of one embodiment of a transfer process that utilizes a transfer head.

FIG. 4 is a schematic side view of an apparatus showing part of another embodiment of a transfer process that utilizes a transfer head.

FIG. 5 is a schematic side view of another part of the process of FIG. 4.

FIG. 6 is a schematic side view of a portion of a transfer apparatus showing part of another embodiment of a transfer process that utilizes a transfer head.

FIG. 7 is a schematic perspective view of one embodiment of an apparatus for forming a transfer head.

FIG. 8 is a flowchart of one embodiment of a method of forming a transfer head.

FIG. 9 is a surface profile pot of an exemplary transfer layer.

FIG. 10 is a graph of specular reflectivity vs. substrate temperature of an exemplary switchable polymer.

FIG. 11 is a graph of derivative plots of curves of FIG. 10.

### DETAILED DESCRIPTION

In general, the present disclosure provides various embodiments of a transfer head and a method of manufacturing such transfer head. The transfer head can include a transfer layer with thermally- or optically-activated, repeatable, and reversible rigid-to-soft transitions to facilitate object (e.g., chiplet) mass transfer. In one or more embodiments, the transfer layer can be formed by disposing a polymer precursor material onto a substrate that is heated to a first temperature Ti that is greater than a melting point temperature Tₘ of the polymer precursor material. The polymer precursor material forms a coated substrate that can be exposed to electromagnetic radiation while the temperature of the coated substrate is maintained at Ti. While the coated substrate remains exposed to the electromagnetic radiation, the temperature of the substrate can be reduced to a second temperature T₂ that is less than Tₘ. The coated substrate can then be removed from exposure to the electromagnetic radiation to form the transfer layer, which includes a thermally-switchable shape memory polymer material.

Polymer alloys that switch characteristics from a high elastic modulus state to a low elastic modulus state at a phase transition temperature can be utilized to form transfer heads for picking and placing microscopic objects. To achieve this functionality, the switchable polymer can be formed into a planar film that retains its switchable phase transition properties.

Methods of manufacturing these switchable polymer films have previously involved assembling a mold, embedding physical spacers within the mold chamber, filling the chamber with melted polymer precursor material via capillary action, and, after polymer cure, releasing the mold. Typical setups can include two glass pieces that are pressed against sandwiched spacers to form a gap. One of the glass pieces is coated with an adhesion promoter, while the other piece is coated with an anti-adhesion agent. The cavity formed between the two glass pieces functions as a mold into which a molten polymer mix is filled. The filling process is usually performed using capillary action by feeding a heated polymer precursor material into one edge of the mold. Once cured, the glass piece with the anti-adhesion agent is forcibly removed, leaving a solid switchable polymer film on the other, adhesion promoting-coated substrate.

The switchable polymer material is solid at room temperature, so the capillary fill must be performed at elevated temperatures, which can make the relative positioning and manipulation of fixtures and constituent chemicals cumbersome. The filled mold must then be transferred to a vacuum oven and, after vacuum treatment and still in liquid form, cured under UV illumination. The physical movements arising from these transport processes frequently lead to the molten polymer partially or fully leaking out of the mold. Also, the capillary fill process is not easily scalable to large contiguous sizes because viscous fluid entering the mold from an edge opening cannot easily traverse long distances to fill small gaps, especially if the mold has embedded spacers within the gap that can obstruct the fill path. The last step in the fabrication process involves taking apart the mold by forcibly prying out the top plate. The process requires applying an anti-adhesion agent on the top plate of the mold to enable its release, which adds complexity to the process. Further, the mold is difficult to pry apart after polymer cure despite the anti-adhesion coating, and the release process frequently leads to film or substrate damage.

Various embodiments of transfer heads and methods of manufacturing such heads described herein can exhibit one or more advantages over known transfer heads and methods.

For example, instead of utilizing a mold, one or more embodiments of a transfer layer can be disposed on a substrate by spinning, casting, doctor blade coating, printing, screen printing, or spraying a polymer precursor material on a heated substrate, followed by curing the material in vacuum under UV illumination. The elevated substrate temperature can be continuously maintained above the melting point temperature of the polymer material when transitioning from the melt deposition process to the vacuum UV cure. Further, exposure of the coated substrate to electromagnetic radiation can be maintained during a cool down process to provide a full cure.

By using these coating techniques as opposed to currently-used mold techniques, thermally-switchable shape memory polymer transfer layers can be formed more quickly, e.g., in less than 3 hours, compared to current transfer layers that typically require 40 hours to form. Additionally, one or more of the techniques described herein can be scalable such that large-area contiguous uniform films can be more easily fabricated. Further, these techniques can be utilized to form switchable polymer transfer layers on a variety of substrates, including silicon, flexible stainless steel, flexible plastic, glass, and substrates with patterned light absorbers such as carbon, amorphous silicon (a-Si), indium tin oxide (ITO), and metal, and color-conversion molecules. Further, various embodiments of transfer heads for picking and placing micro-objects employing modulus-switchable polymer films described herein can be formed using non-capillary fill techniques. Such techniques can mitigate issues associated with traditional capillary-fill methods, such as fixture handling complexity, difficulty forming large area transfer heads, and low fabrication yield due to challenges in releasing the mold after polymer cure.

The present disclosure relates to manipulation and assembly of objects, and in some embodiments the mass assembly of micro-objects via a transfer substrate. Some electronic devices are fabricated by mechanically overlaying small objects on top of each other. While micro-electronic and micro-optical components are sometimes manufactured using wafer formation techniques such as layer deposition, masking, and etching, certain classes of materials are not growth-compatible with each other. In such a case, the assembly may involve forming one class of devices on a first substrate and a second class of devices on a second substrate, and then mechanically joining them, e.g., via flip-chip or transfer printing techniques.

Aspects described herein relate to a system that is capable of selectively transferring large number of micro-objects (e.g., particles, chiplets, mini/micro-LED dies) from a donor substrate to another substrate while maintaining high position registration of the individual micro-objects. This system may be used for assembling devices such as microLED displays.

Generally, microLED displays are made with arrays of microscopic LEDs forming the individual transfer elements. Both OLED displays and microLED displays offer greatly reduced energy requirements compared to conventional LCD systems. Unlike OLED, microLED is based on conventional LED technology, which offers higher total brightness than OLED produces, as well as higher efficiency in terms of light emitted per unit of power. It also does not suffer from the shorter lifetimes of OLED.

A single 4K television utilizing microLED has ˜25 million small LED subpixels that need to be assembled. Mass transfer of chiplets is one technology that may be used for microLED manufacturing. Transferring microLEDs to a target backplane quickly and accurately with a high yield will be one of the techniques that manufacturers need to perfect for microLED to be a viable mass-market product.

The techniques described herein can be used for microLED manufacture, as well as other assembly procedures in which a large number of (typically) small objects need to be moved at once, and where it may be necessary to selectively move a subset of such device to and/or from the transfer media. Such micro-objects may include but are not limited to inks, pre-deposited metal films, silicon chips, integrated circuit chips, beads, microLED dies, lasers, waveguides, photonic components, micro-electro-mechanical system (MEMS) structures, and any other pre-fabricated microstructures. In the present disclosure, these objects may be collectively referred to as “chiplets” in that they are small, individually separable devices or structures amenable to selective mass-transfer from a source to a target.

Selective transfer of chiplets in an arbitrary pattern is useful to facilitate the effective transfer process, pixel repair, and hole/vacancy refill for microLED display manufacturing, which will lead to high process yield. An elastomer stamp has been used to deterministically transfer microscale LED chips for this type of application. However, an elastomer stamp has a fixed pattern and cannot transfer arbitrary pattern of chiplets. Inevitably, some subset of the chiplets will be defective; therefore, it can be difficult to replace a select few of them using such a stamp.

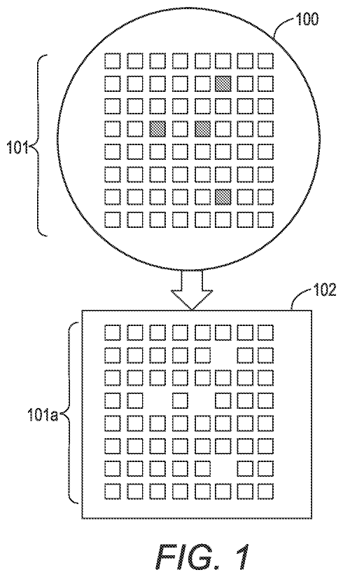

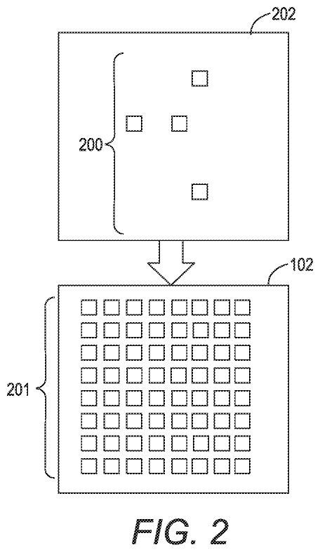

In FIGS. 1 and 2, block diagrams show an example of an assembly process that can be achieved using devices, systems, and methods according to example embodiments. In FIG. 1, a donor wafer/substrate 100 is shown that includes an array of chiplets 101 that may have been grown or placed on the substrate or surface 100. The shaded chiplets in the array 101 have been identified as defective, and when the chiplets are transferred to a target substrate 102, only a subset 101a of the chiplet array is transferred, namely the functional chiplets that are not shaded. This may be achieved with a transfer head 202 as shown in FIG. 2 that can selectively pick up just the subset 101a from the donor substrate 100 once they are identified. As shown in FIG. 2, the transfer head 202 can subsequently pick up a second set of chiplets 200 (e.g., from a different donor substrate). The locations of the chiplets within the set 200 correspond to the locations of the defective chiplets on the first donor substrate 100. The transfer head 202 moves this set 200 to the target substrate 102, resulting in a full set 201 of operational chiplets being located on the target substrate 102.

As mentioned herein, the transfer head includes the transfer layer that can be activated at predetermined locations to selectively hold and transfer an array of micro-objects on the substrate of the transfer head. Even when the whole transfer layer is in contact with the array of micro-objects, only the subset will adhere to the transfer head and be transferred, and the objects outside the subset will be left behind or otherwise unaffected. Similarly, the transfer layer may be able to selectively release a subset of micro-objects that are currently attached to the transfer layer such that only the part of the held objects are released. The transfer layer may non-selectively release the subset as well, e.g., release all chiplets currently held regardless of position. The activation process is repeatable and reversible, such that no permanent bonding or sacrificial material is needed to affect the selective holding or releasing of the objects.

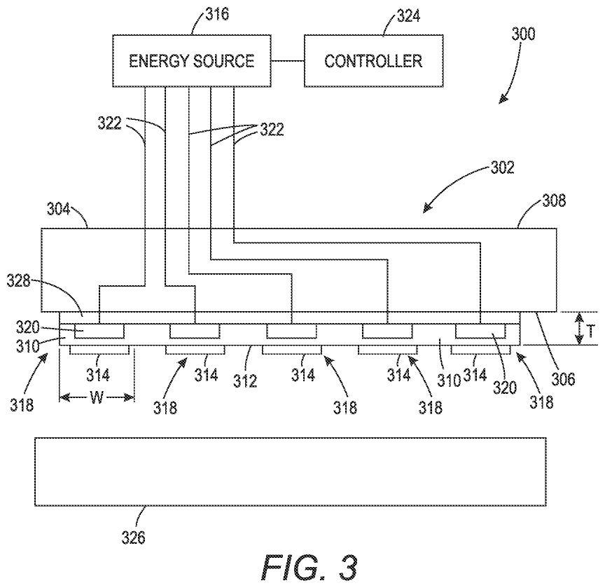

Any suitable type of energy source can be utilized with the transfer head to activate and deactivate predetermined regions of the transfer layer to selectively hold and transfer micro-objects. In one or more embodiments, the energy source can be an electrical energy source as is further described, e.g., in U.S. Pat. No. 11,302,561 to Wang et al. and entitled TRANSFER ELEMENTS THAT SELECTABLY HOLD AND RELEASE OBJECTS BASED ON CHANGES IN STIFFNESS. Further, in one or more embodiments, the energy source can be an optical energy source as is further described, e.g., in U.S. patent application Ser. No. 17/875,610 to Chua et al. and entitled OPTICALLY ACTIVATED OBJECT MASS TRANSFER APPARATUS. For example, FIG. 3 is a schematic side view of one embodiment of a transfer apparatus 300. The transfer apparatus 300 includes a transfer head 302 having a substrate 304 that includes a first major surface 306 and a second major surface 308. The transfer head 302 further includes a transfer layer 310 that, in one or more embodiments, can be spin coated onto the first major surface 306 of the substrate 304. The transfer layer 310 includes a transfer surface 312 opposite the first major surface 306 of the substrate 304. The transfer layer 310 can include a thermally-switchable shape memory polymer material that undergoes a phase change when heated. Further, the transfer surface 312 of the transfer layer 310 can be configured to be placed in contact with an outward-facing side of an object 314 (e.g., chiplet) during a transfer operation. In one or more embodiments, the transfer layer 310 has a total thickness variation of less than 8 micrometers.

The transfer apparatus 300 further includes an energy source 316 configured to apply energy to the transfer head 302 to selectively heat one or more regions 318 of the transfer layer 310 that correspond to a location of the object 314, where the region is configured to hold the object when the energy is removed during the transfer operation. The region 318 is configured to be subsequently heated during the transfer operation to release the object 314. In one or more embodiments, the transfer layer 310 is reusable for repeated transfer operations.

The transfer head 302 can take any suitable shape and have any suitable dimensions.

Further, the substrate 304 of the transfer head 302 can also take any suitable shape and have any suitable dimensions. For example, the substrate 304 may have any suitable thickness, e.g., a thickness range from several tens of micrometers to several millimeters and lateral dimensions from several millimeters to one meter. The substrate 304 can also include any suitable material, e.g., at least one of glass, quartz, silicon, polymer, or silicon carbide (SiC).

Disposed on the first major surface 306 of the substrate 304 is the transfer layer 310. The transfer layer 310 can be a continuous layer. In one or more embodiments, the transfer layer 310 can be patterned using any suitable technique to provide two or more transfer elements, which correspond to the regions 318 that are configured to be subsequently heated during the transfer operation. The regions 318 of the transfer layer 310 can selectively be made to change stiffness, which can be expressed as the Young's modulus of the material from which the elements are made. The Young's modulus is a measure of stress (force per unit area) divided by strain (proportional deformation) in a material in the linear elasticity regime. Generally, materials with higher Young's modulus (lower strain for a stress a) are stiffer than a material with lower Young's modulus (higher strain for the same a). Other measures may also be used to represent stiffness of a material, such as storage modulus, which also accounts for dynamic performance of the material. Some measures may be used to represent stiffness of a part, such as a spring constant, that may be functionally equivalent in defining performance of the part. However the stiffness is defined, the transfer layer 310 can exhibit a change in stiffness in response to temperature that can be utilized in device transfer as described herein. The transfer layer 310 can have a higher Young's modulus >6 MPa at a lower temperature and a lower Young's modulus <1 MPa at a higher temperature.

The transfer layer 310 can take any suitable shape and have any suitable dimensions. For example, the transfer layer 310 can have any suitable thickness, e.g., at least 0.1 microns and no greater than 5 cm. Further, the transfer layer 310 can have any total thickness variation value, e.g., less than 0.1% of the nominal thickness, less than 8 micrometers, or less than 0.05 micrometers. As used herein, the term “total thickness variation” means a maximum difference in a thickness of the transfer layer 310 across a given cross-section as measured using standard physical (such as profilometer of atomic force microscope) or optical (such as interferometer or ellipsometer) techniques.

Each region 318 of the transfer layer 310 can also include a thermal element 320 that is configured to change a temperature of the respective region in response to an input, e.g., via inputs 322. A controller 324 is coupled to provide the inputs 322 to the thermal elements 320, thereby causing a subset of the regions 318 to selectively pick up and hold objects 314 to and (optionally) release the objects from the transfer head 302. In particular, the objects 314 will not stick to the transfer layer 310 at the lower temperature but will stick at the higher temperature. To increase the reliability of the adhesion, one or more regions 318 of the transfer layer 310 may be cooled before attempting to pull the objects 314 away from transfer head 302.

The transfer apparatus 300 may be part of a micro-transfer system, which is a system used to transfer micro-objects (e.g., 1 μm to 1 mm) from the transfer head 302 to a target substrate 326. The transfer layer 310 may be formed of a multi-polymer that contains stearyl acrylate-based (SA). In such a case, a difference between the higher and lower temperatures may be less than 20° C. (or in other cases less than 50° C.) to adjust the tackiness of the transfer layer 310 such that there is a marked difference in surface adhesion and Young's modulus, e.g., from <1 MPa at the higher temperature to >6 MPa at the higher temperature. The controller 324 in such a system may be coupled to actuators that induce relative motion between substrates to facilitate object transfer.

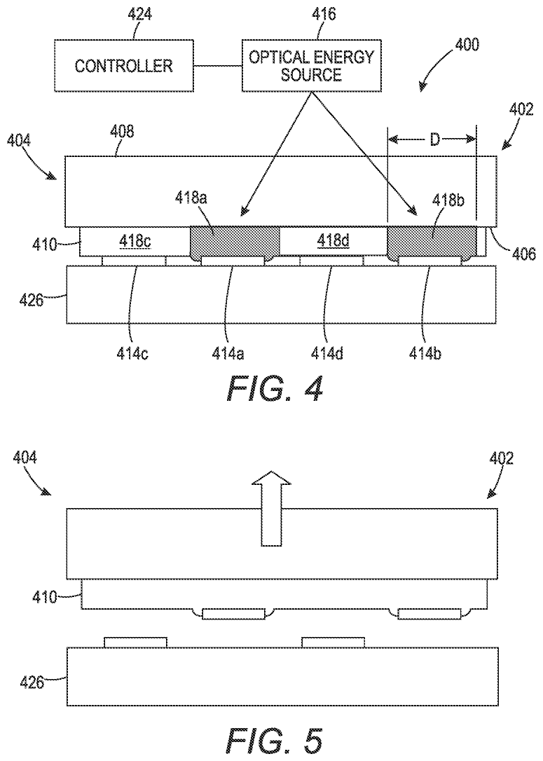

Each thermal element 320 may include one or both of a heating element and a cooling element. The inputs 322 may include electrical signals and/or laser light (FIG. 4). The inputs 322 may be configured (e.g., using a matrix circuit) such that there are fewer lines going to the energy source 316 than the total number of regions 318 of the transfer layer 310. The transfer head 302 may further include a thermal insulator 328 disposed between the transfer layer 310 and the transfer substrate 304. The insulator 328 helps prevent heat transfer to the substrate 304, thereby decreasing the amount of energy needed to affect temperature change at the transfer layer 310 and decrease response time.

Generally, the transfer layer 310 forms the intermediate transfer surface 312 whose compliance can be modulated (e.g., have a sharp rigid-to-soft transition) as a function of temperature. Such a surface 312 can be used to pick up and release groups of micro-objects 314 in a controlled and selectable manner. Each region 318 of the transfer layer 310 may have lateral dimensions W from several micrometers to several hundreds of micrometers. Each region 318 may have a total thickness T from less than one micron to several hundred micrometers. The pitch of the transfer array may vary from several micrometers to several millimeters. As shown in FIG. 3, the thermal elements 320 and thermal insulator 328 are continuous layers that are not physically isolated from one another. As such, each region 318 where the heating/cooling elements can be individually addressed and controlled defines a transfer element.

Note that, while the illustrated embodiments show two or more regions 318, in some cases a single region may be used. For example, a single region 318 may be part of a manipulator that is placed at the end of a robotic arm. In such a configuration, a single region 318 may be used to pick up objects without requiring the use of pincers, vacuum, magnetics, etc. In other configurations, one or more regions 428 may be placed at the ends of pincers or other holding appendages to assist in gripping without having to apply undue pressure on the object being held.

As with the other embodiments, a thermal element 320 can increase change adhesion (corresponding to a change in Young's modulus) during holding and releasing operations.

Phase-changing polymers including stearyl acrylate (SA) has been studied as a bistable electroactive polymer (BSEP) for use in the adhesion element. The BSEP polymer is a rigid polymer below its glass transition temperature (T_{g}). Above T_{g}, it becomes an elastomer that exhibits large elongation at break and high dielectric field strength. Electrical actuation can be carried out above Tg with the rubbery BSEP functioning as a dielectric elastomer. The deformation is locked when cooling down the polymer below Tg. The shape change can be reversed when the polymer is reheated above Tg.

Stearyl acrylate (octadecyl acrylate, SA) based polymers have been investigated as shape memory polymers due to their sharp phase transition between the crystalline and molten states of the stearyl moieties. The abrupt and reversible phase transition of the crystalline aggregates of the stearyl moieties results in a rapid shift between the rigid and rubbery states of the polymers during temperature cycles. The transition of SA is typically below 50° C. with a narrow phase change temperature range of less than 20° C. Therefore, SA is an ideal component for imparting a sharp rigid-to-rubbery transition.

The transfer layer 310 may be made of materials including but not limited to stearyl acrylate (octadecyl acrylate, SA) based polymers, stearyl acrylate and urethane diacrylate copolymer or other types of polymers. In particular, a copolymer containing urethane diacrylate and SA has been found to have desirable characteristics for these purposes. The transfer layer 310 may preferably have a sharp rigid-to-soft transition; therefore, the adhesion can be easily modulated with temperature change. Tₘ refers to the melting temperature of the polymer precursor materials that, when properly mixed, processed, and cured, becomes the shape memory polymer. The shape memory polymer (end product after chemical synthesis) has a property of becoming “gel-like” above a phase transition temperature T_{g}.

The thermal elements 320 could be thermoelectric heating/cooling elements, resistive heaters, diode heaters, inductive heating elements, optical heating elements, etc. The thermal elements 320 may include thin film resistors, a diode structure, and/or or high optical energy absorbing efficiency materials such as carbon black, carbon nanotubes, engineered nanoparticles, etc. In one or more embodiments, the thermal elements 320 are electrically-activated thermal elements. Further, in one or more embodiments, the thermal elements 320 are optically activated thermal elements (FIG. 4). The thermal insulator 328 may be made from materials such as polyimide, PDMS, parylene, glass, silicon oxide, AlₓO_{y} and SₓN_{y}, and combinations thereof.

As mentioned herein, any suitable energy source may be utilized with a transfer head to activate one or more transfer regions within a transfer layer. For example, FIGS. 4-5 are schematic side views that illustrate details of an apparatus 400 according to an example embodiment that includes an optical energy source 416. As seen in FIG. 4, the apparatus 400 also includes a transfer head 402 with a transfer layer 410 formed on a first major surface 406 of a base structure or substrate 404. Portions of the transfer layer 410 can selectively be made to change stiffness via the application and removal of heat to a localized region. The change in mechanical properties of the transfer layer 410 may also be referred to herein as a phase change, e.g., from a solid state to a gelatinous/liquid state.

The transfer/adhesion layer 410 has a higher Young's modulus (e.g., >6 MPa) at a lower temperature and a lower Young's modulus (e.g., <1 Mpa) at a higher temperature. An optical energy source 416 (e.g., a laser) is operable to change a temperature of one or more regions 418 of the transfer layer 410 in response to an input from a controller 424. In this case, the optical energy source 416 is coupled to heat regions 418a, 418b of the transfer layer 410 (the heating indicated by shading), while regions 418c and 418d are not heated. This example illustrates how the transfer layer 410 can selectively pick up a subset of objects 414a, 414b from a source substrate 426 while leaving a second subset of objects 414c, 414d attached to the source substrate.

The heated regions 418a, 418b can deform around the objects 414a, 414b during the heating, and when the optical energy is removed, the regions 418a, 418b re-solidify, thereby holding onto the objects 414a, 414b. When the transfer head 402 is moved away from the source substrate 426 as shown in FIG. 5, objects 414a, 414b will be pulled from the source substrate 426 while objects 414c, 414d remain on the source substrate 426. When the transfer head 402 is moved over and in contact with a target substrate/backplane (not shown), the regions 418a, 418b are reheated either via the optical energy source 416 or a different energy source, allowing the objects 414a, 414b to be released onto the target substrate 426, which may have means for holding, adhering to, or attracting the objects 414a, 414b to ensure separation from the transfer head 402. Note that in the release phase, the entire transfer layer 410 may be heated and not just regions 418a, 418b, assuming that all currently attached chiplets are to be released.

The apparatus 400 may be part of a micro-transfer system. Further, the transfer layer 410 may be formed of a multi-polymer that contains stearyl acrylate-based (SA). In such a case, a difference between the higher and lower temperatures may be less than 20° C. (or in other cases less than 50° C.) to adjust the tackiness of the transfer layer 410 such that there is a marked difference in Young's modulus, e.g., from <1 Mpa at the higher temperature to >6 Mpa at the lower temperature. The controller 424 in such a system may be coupled to actuators (not shown) that induce relative motion between the transfer head 402 and substrates to facilitate object transfer as described herein. The transfer layer 410 may be made of materials including but not limited to stearyl acrylate (octadecyl acrylate, SA) based polymers, stearyl acrylate and urethane diacrylate copolymer or other types of polymers. In particular, a copolymer containing urethane diacrylate and SA has been found to have desirable characteristics for these purposes. The transfer layer 410 may preferably has a sharp rigid-to-soft transition therefore the adhesion can be easily modulated with temperature change.

The transfer layer materials described above can be transparent at laser wavelengths commonly used in mass assembly systems, e.g., green and blue lasers. Thus, when using lasers of these wavelengths, the transfer layer 410 may not be directly heat-able by the optical energy source 416 but can instead be heated by an optical absorber proximate the inward and/or outward facing surfaces of the transfer layer. In other embodiments, the transfer layer 410 may include adaptations that allow it to be directly optically heated without the use of a separate optical absorber layer.

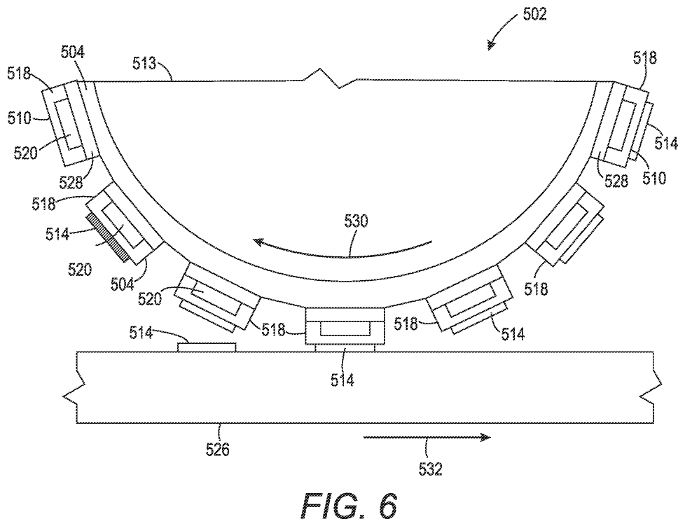

As mentioned herein, the transfer head can take any suitable shape and have any suitable dimensions. For example, FIG. 6 is a schematic side view of a portion of a transfer apparatus that includes a transfer head 502 according to another example embodiment. The transfer head 502 includes a transfer substrate 504 that includes a transfer layer 510 that has been patterned using any suitable technique to include two or more transfer regions or elements 518 each having a surface adhesion that varies by temperature. Each of the transfer elements 518 also includes a thermal element 520 configured to change a temperature of the transfer element in response to an input. Each of the transfer elements 518 also includes an insulator 528 that thermally insulates the thermal element 520 from the transfer substrate 504.

In this embodiment, the transfer substrate 504 is curved and mounted to a roller 513 that rotates relative to a target substrate 526. The roller 513 and target substrate 526 also move linearly relative to one another (horizontally in this illustration) such that only a subset of the transfer elements 518 (e.g., a single element 518) contacts the transfer substrate at a time. The subset of transfer elements 518 are selectively activated to hold or release an object 514, such that some of the objects 514 are selectively transferred to the target substrate 526. Note that the shaded object 514 to the left of the figure was not transferred to the target substrate 526. Note another part of the roller 513 and substrate 504 may be in contact with a donor substrate (not shown) such that the transfer of objects may be a rolling transfer process where objects 514 are picked up from the donor and transferred to the target 526.

The roller 513 and substrate 504 may be in contact with the donor and target substrates at the same times, or different times. In such a case, a second transfer substrate (not shown) may be used to deposit discarded objects 514, and this second transfer substrate may also use a curved substrate. Any of the other embodiments described herein may use a curved transfer substrate and rolling transfer process as shown in FIG. 6. As indicated by arrows 530, 532, the transfer may be facilitated by a rotational actuator 530 that rotates the roller 513 and a linear actuator 532 that induces relative linear motion between the roller and the substrate 526.

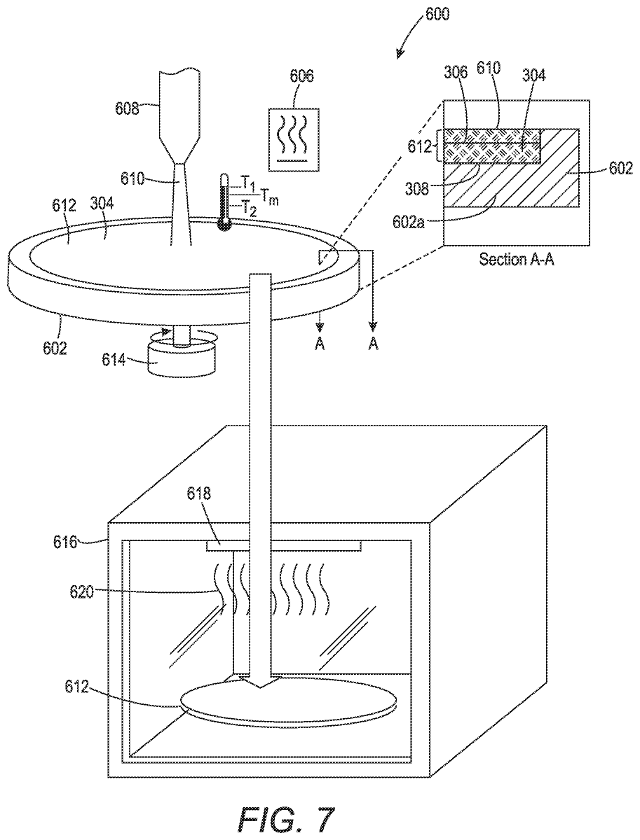

Any suitable system or collection of apparatuses can be utilized to manufacture the various embodiments of transfer heads described herein. For example, FIG. 7 is a schematic view of one embodiment of a system 600 for manufacturing the transfer head 302. Although described regarding the transfer head 302 of FIG. 3, the system 600 can be utilized to manufacture any suitable transfer head. The system 600 includes a mounting fixture 602 for holding the substrate 304. The second major surface 308 of the substrate 304 is disposed on a base 602a of the mounting fixture 602. The system 600 further includes a heating apparatus 606 configured to heat the substrate 304 to any suitable temperature. In one or more embodiments, the heating apparatus 606 is configured to heat the substrate 304 to a first temperature T₁ greater than a melting point temperature Tₘ (typically 40 to 80° C. depending on the constituent chemical blend) of a polymer precursor material 610 that is disposed on the substrate. The system 600 further includes a dispenser 608 configured to dispose the polymer precursor material 610 on the first major surface 306 of the substrate 304 to form a coated substrate 612 (i.e., the substrate 304 and the transfer layer 310). The polymer precursor material 610 can include any suitable polymer material, e.g., a bistable electroactive polymer (BSEP). In one or more embodiments, Tₘ is about 50° C. and T₁ is about 75° C. The polymer precursor material 610 is kept above its melting point, typically about 60 to 70° C., so that it is a liquid during the dispensing process.

The system 600 further includes a smoothing apparatus 614 configured to distribute the polymer precursor material 610 on the first major surface 306 of the substrate 304 to further form the coated substrate 612. The smoothing apparatus 614 can be configured to use any suitable technique to distribute the polymer precursor material 610 on the substrate 304, e.g., spin coating, casting, doctor blade coating, printing, or spraying. A vacuum chamber 616 is configured to receive the coated substrate 612. Further, an electromagnetic radiation source 618 is configured to direct electromagnetic radiation 620 to the coated substrate 612 in a vacuum environment when the coated substrate is disposed in the vacuum chamber 616. Any suitable vacuum environment can be utilized, e.g., a nitrogen environment. The electromagnetic radiation source 618 can include any suitable source or sources that are configured to provide any suitable type of electromagnetic radiation, e.g., ultraviolet radiation. The heating apparatus 606 is further configured to maintain the temperature of the coated substrate 612 at T₁ as the electromagnetic radiation 620 is directed to the coated substrate 612, and reduce the temperature of the coated substrate to a second temperature T₂ less than Tₘ while maintaining exposure of the coated substrate to the electromagnetic radiation.

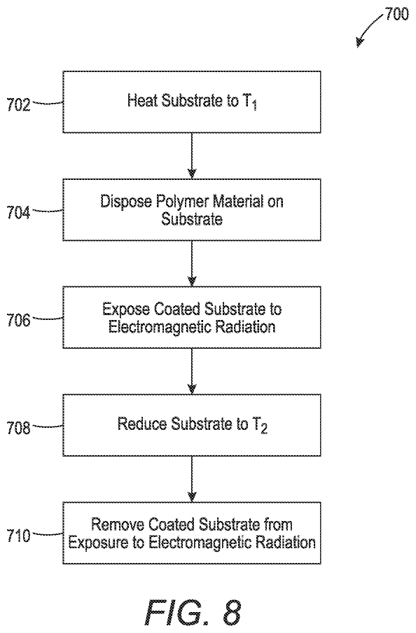

Further, any suitable technique can be utilized to form the various embodiments of transfer heads described herein. For example, FIG. 8 is a flowchart of one embodiment of a method 700 for forming the transfer head 302. Although described regarding the transfer head 302 of FIG. 3 and the system 600 of FIG. 7, the method 700 can be utilized to form any suitable transfer head utilizing any suitable system. At 702, the substrate 304 is heated to a first temperature T₁ greater than a melting point temperature Tₘ of the polymer precursor material 610 using any suitable technique. For example, the substrate 304 can be disposed on the base 602a of mounting fixture 602 of FIG. 7 and heated utilizing heating apparatus 606. Prior to or after heating the substrate 304, the polymer precursor material 610 can be heated above the melting point temperature Tₘ using any suitable technique. At 704, the heated polymer precursor material 610 is disposed on the first major surface 306 of the substrate 304 to form the coated substrate 612 (i.e., the substrate 304 and the transfer layer 310). The polymer precursor material 610 can include any suitable polymer material. Any suitable technique can be utilized to dispose the polymer precursor material 610 on the first major surface 306 of the substrate. In one or more embodiments, the polymer precursor material 610 can be spin coated on the first major surface 306 of the substrate 304 by, e.g., placing the substrate on the base 602a of the mounting fixture 602 and rotating the mounting fixture and substrate with the smoothing apparatus 614. In one or more embodiments, the polymer precursor material 610 can be disposed on the first major surface 306 of the substrate 304 utilizing at least one of casting, doctor blade coating, printing, or spraying the polymer precursor material on the first major surface of the substrate utilizing the smoothing apparatus 614.

Prior to disposing the polymer precursor material 610 on the substrate 304, an adhesion promoting layer can be disposed on the first major surface 306 of the substrate such that the polymer precursor material is disposed on at least a portion of the adhesion promoting layer.

The coated substrate 612 can be exposed to electromagnetic radiation 620 at 706 while maintaining the temperature of the coated substrate 612 at Ti. Any suitable electromagnetic radiation can be utilized, e.g., ultraviolet radiation. Prior to exposing the coated substrate 612 to electromagnetic radiation 620, the coated substrate 612 can optionally be placed in a vacuum (e.g., in vacuum chamber 616) while maintaining the temperature of the coated substrate at Ti. Further, the polymer precursor material 610 can optionally be heated to at least temperature Ti using any suitable technique prior to disposing the polymer precursor material on the first major surface 306 of the substrate 304. In one or more embodiments, one or more thermal elements 320 can optionally be disposed or fabricated on the first major surface 306 of the substrate 304 prior to disposing the polymer precursor material 610 on the first major surface of the substrate. In such embodiments, the polymer precursor material 610 can be disposed on the first major surface 306 of the substrate 304 and at least a portion of one or more of the thermal elements 320 such that the thermal element is disposed between the substrate and at least a portion of the polymer precursor material.

At 708 the temperature of the substrate 612 is reduced to a second temperature T₂ less than the melting point temperature Tₘ of the polymer precursor material 610 while maintaining exposure of the coated substrate to the electromagnetic radiation 620. Further, the method 700 includes removing the coated substrate 612 from exposure to the electromagnetic radiation 620 at 710 to form the transfer layer.

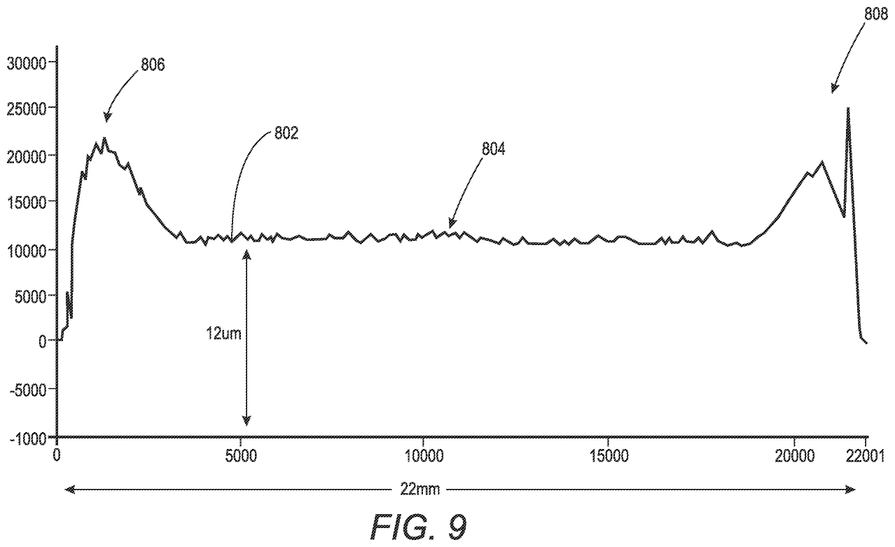

In one or more embodiments, one or more edge portions of the coated substrate 612 can be removed after the coated substrate is removed from exposure to the electromagnetic radiation 620. For example, FIG. 9 is a surface profile plot 802 of an exemplary transfer layer that was spin-coated onto a substrate. The transfer layer exhibits uniform thickness across a substantial central region 804 of the layer. Edge regions 806, 808, however, include high protrusions, which can be edge beads arising from known fluid spin dynamics. These edge beads can be removed using any suitable technique as part of the manufacture of the transfer head, or the edge portion of the substrate containing edge regions can be cut off from the central region, thereby providing a more uniform transfer layer.

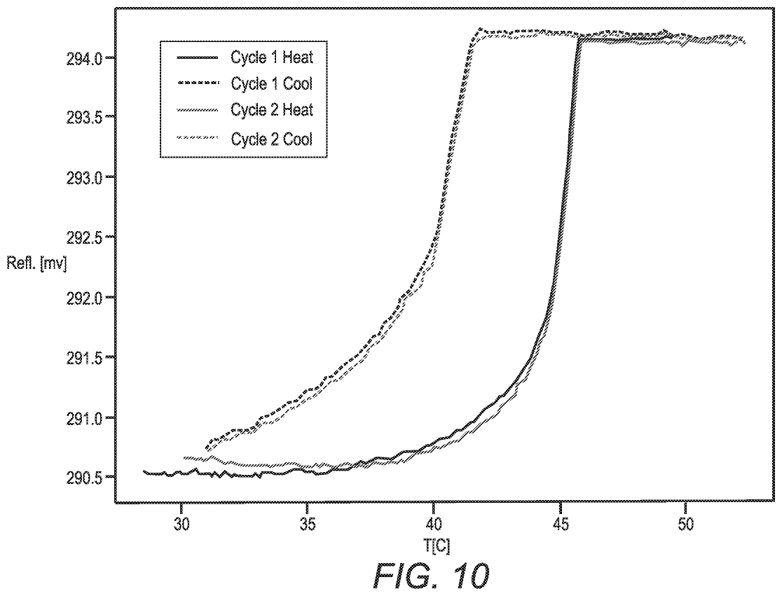

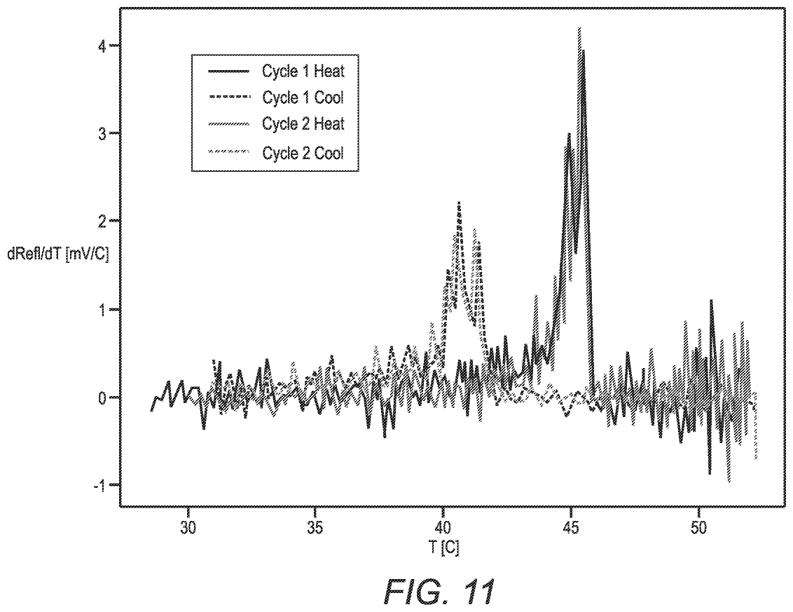

In general, the temperature at which the polymer of the transfer layer of the transfer head switches states can be characterized by monitoring specular surface reflectivity of the layer. Below the transition temperature, the polymer exhibits high elastic modulus and is rough, so the specular reflectivity is low. The surface condition changes abruptly at the transition temperature from rough to smooth, and the specular reflectivity increases sharply. For example, FIG. 10 is a graph of specular reflectivity vs. substrate temperature of a switchable stearyl acrylate polymer formed on a flexible stainless-steel substrate using the process described herein over two temperature ramp cycles. The curves in FIG. 10 indicate that the polymer switches states at a substrate temperature of about 45° C. during the temperature ramp-up cycle. During the ramp-down cycle, the transition temperature occurs when the substrate cools to around 40° C. This difference in substrate temperature at which the polymer switches states is caused by the thermal mass of the substrate, which causes the temperature at the polymer to differ slightly from that at the bottom of the substrate during the ramp up and ramp down cycles. The data suggest that the phase transition temperature of the polymer is between 4° and 45° C. The derivative plots of the curves are shown in FIG. 11, showing peaks where the transition temperatures occur. The polymer switching characteristics in FIGS. 10-11 are repeatable across repeated temperature cycles, as indicated by the overlapping curves for cycles 1 and 2.

All references and publications cited herein are expressly incorporated herein by reference in their entirety into this disclosure, except to the extent they may directly contradict this disclosure. Illustrative embodiments of this disclosure are discussed and reference has been made to possible variations within the scope of this disclosure. These and other variations and modifications in the disclosure will be apparent to those skilled in the art without departing from the scope of the disclosure, and it should be understood that this disclosure is not limited to the illustrative embodiments set forth herein. Accordingly, the disclosure is to be limited only by the claims provided below.

What is claimed is:

1. A method of forming a transfer head comprising a transfer layer that comprises a thermally-switchable shape memory polymer material, the method comprising:
heating a polymer precursor material above a melting point temperature Tₘ of the polymer precursor material;
heating a substrate to a first temperature T₁ greater than Tₘ, wherein the substrate comprises a first major surface and a second major surface;
disposing the heated polymer precursor material on the first major surface of the substrate to form a coated substrate;
exposing the coated substrate to electromagnetic radiation while maintaining the temperature of the coated substrate at Ti;
reducing the temperature of the substrate to a second temperature T₂ less than Tₘ while maintaining exposure of the coated substrate to the electromagnetic radiation; and
removing the coated substrate from exposure to the electromagnetic radiation to form the transfer layer.

2. The method of claim 1, further comprising, prior to exposing the coated substrate, placing the coated substrate in a vacuum while maintaining the temperature of the coated substrate at Ti.

3. The method of claim 1, further comprising disposing an adhesion promoting layer on the first major surface of the substrate prior to disposing the polymer precursor material on the first major surface of the substrate such that the polymer precursor material is disposed on at least a portion of the adhesion promoting layer.

4. The method of claim 1, wherein the transfer layer comprises a copolymer containing urethane diacrylate and stearyl acrylate.

5. The method of claim 1, wherein disposing the polymer precursor material on the first major surface of the substrate comprises spin coating the polymer precursor material on the first major surface of the substrate.

6. The method of claim 1, wherein disposing the polymer precursor material on the first major surface of the substrate comprises at least one of casting, doctor blade coating, printing, or spraying the polymer precursor material on the first major surface of the substrate.

7. The method of claim 1, further comprising removing an edge portion of the coated substrate after removing the coated substrate from exposure to the electromagnetic radiation.

8. The method of claim 1, further comprising fabricating a thermal element on the first major surface of the substrate prior to disposing the polymer precursor material on the first major surface of the substrate, wherein disposing the polymer precursor material comprises disposing the polymer precursor material on the first major surface of the substrate and at least a portion of the thermal element such that the thermal element is disposed between the substrate and at least a portion of the polymer precursor material.

9. The method of claim 1, wherein the electromagnetic radiation comprises ultraviolet radiation.

10. The method of claim 1, wherein the polymer precursor material comprises a bistable electroactive polymer (BSEP).

11. The method of claim 1, wherein the polymer precursor material comprises stearyl acrylate.

12. A transfer head comprising:
a substrate comprising a first major surface and a second major surface; and
a transfer layer spin coated onto the first major surface of the substrate and comprising a transfer surface opposite the first major surface of the substrate, wherein the transfer layer comprises a thermally-switchable shape memory polymer material that undergoes a phase change when heated, and further wherein the transfer surface of the transfer layer is configured to be placed in contact with an outward-facing side of a chiplet during a transfer operation;
wherein the transfer layer has a total thickness variation of less than 8 micrometers.

13. The transfer head of claim 12, further comprising an optical absorber material disposed between the first major surface of the substrate and the transfer layer.

14. The transfer head of claim 12, further comprising a thermal element disposed on the first major surface of the substrate between the substrate and the transfer layer, wherein the thermal element is configured to change an operating temperature of a selected region of the transfer layer in response to an input.

15. A transfer apparatus comprising:
a transfer head comprising:
a substrate comprising a first major surface and a second major surface; and
a transfer layer spin coated onto the first major surface of the substrate and comprising a transfer surface opposite the first major surface of the substrate, wherein the transfer layer comprises a thermally-switchable shape memory polymer material that undergoes a phase change when heated, and further wherein the transfer surface of the transfer layer is configured to be placed in contact with an outward-facing side of a chiplet during a transfer operation;
wherein the transfer layer has a total thickness variation of less than 5 cm; and
an energy source configured to apply energy to the transfer head to selectively heat a region of the transfer layer that corresponds to a location of the chiplet, wherein the region is configured to hold the chiplet when the energy is removed during the transfer operation, wherein the region is configured to be subsequently heated during the transfer operation to release the chiplet, and further wherein the transfer layer is reusable for repeated transfer operations.

16. The apparatus of claim 15, wherein the transfer head further comprises an optical absorber material disposed between the first major surface of the substrate and the transfer layer.

17. The apparatus of claim 16, wherein the energy source comprises an optical energy source configured to apply optical energy to the optical absorber material to selectively heat the region of the transfer layer that corresponds to the location of the chiplet.

18. The apparatus of claim 15, wherein the energy source further comprises an electrically-activated thermal element disposed on the first major surface of the substrate between the substrate and the transfer layer, wherein the thermal element is configured to selectively heat the selected region of the transfer layer that corresponds to the location of the chiplet.

19. The apparatus of claim 18, further comprising a controller coupled to the transfer head and configured to provide inputs to the thermal element of the transfer head to selectively heat the region.

20. A system for manufacturing a transfer head, comprising:
a mounting fixture for holding a substrate, wherein the substrate comprises a first major surface and a second major surface, wherein the second major surface of the substrate is disposed on a base of the mounting fixture;
a heating apparatus configured to heat the substrate to a first temperature T₁ greater than a melting point temperature Tₘ of a polymer precursor material;
a dispenser configured to dispose the polymer precursor material on the first major surface of the substrate to form a coated substrate, wherein the polymer precursor material comprises a bistable electroactive polymer (BSEP);
a smoothing apparatus configured to distribute the polymer precursor material on the first major surface of the substrate to further form the coated substrate;
a vacuum chamber configured to receive the coated substrate; and
an electromagnetic radiation source configured to direct electromagnetic radiation to the coated substrate in a vacuum environment when the coated substrate is disposed in the vacuum chamber;
wherein the heating apparatus is further configured to:
maintain the temperature of the coated substrate at T₁ as the electromagnetic radiation is directed to the coated substrate; and
reduce the temperature of the coated substrate to a second temperature T₂ less than Tₘ while maintaining exposure of the coated substrate to the electromagnetic radiation.
